(19) United States
(12) Patent Application Publication
(10) Pub. No.: US 2026/0162929 A1
(43) Pub. Date: Jun. 11, 2026

(54) CHARGED PARTICLE BEAM DEVICE AND CONTROL METHOD THEREFOR

(71) Applicant: Hitachi, Ltd., Tokyo (JP)

(72) Inventors: Toshiaki TANIGAKI, Tokyo (JP); Tetsuya AKASHI, Tokyo (JP)

(21) Appl. No.: 19/407,585

(22) Filed: Dec. 3, 2025

(30) Foreign Application Priority Data
Dec. 9, 2024 (JP) 2024-214493

(51) Int. Cl. H01J 37/244; H01J 37/147; H01J 37/20

(52) U.S. Cl. CPC H01J 37/244; H01J 37/1472; H01J 37/20; H01J 2237/002; H01J 2237/24455; H01J 2237/24475; H01J 2237/24585

(57) ABSTRACT

To provide a charged particle beam device that can reduce the influence of a vibration on charged particles which have been transmitted through a sample and a control method therefor.

A charged particle beam device includes a sample holder that holds a sample, an electron source that emits a charged particle beam to be irradiated onto the sample, a detector that detects transmitted particles that are charged particles which have been transmitted through the sample, and a control unit that generates an observation image of the sample based on a detection signal output from the detector and controls each unit and further includes a vibrometer that measures a vibration of the sample holder, an upper deflector that is disposed between the electron source and the sample holder to deflect the charged particle beam, and a lower deflector that is disposed between the sample holder and the detector to deflect the transmitted particles, in which the control unit controls the upper deflector and the lower deflector based on a measured value of the vibrometer to correct deflection of the transmitted particles together with deflection of the charged particle beam.

### 1. TECHNICAL FIELD

The present invention relates to a charged particle beam device.

### 2. DESCRIPTION OF THE RELATED ART

A charged particle beam device typified by a transmission electron microscope is a device that irradiates a sample with a charged particle beam such as an electron beam and detects particles emitted from the sample to obtain an observation image of the sample. In the charged particle beam device, various vibrations, for example, vibrations of a freezer that cools a sample adversely affect observation images.

JP 2018-6338 A discloses a scanning electron microscope that reduces, based on a correction signal generated from vibrations of the sample stage holding a sample and vibrations of the lens barrel having an electron gun emitting a charged particle beam, the influence of the vibrations by correcting the deflection of the charged particle beam irradiated onto the sample.

### SUMMARY OF THE INVENTION

However, JP 2018-6338 A does not consider an adverse effect of vibrations imparted to charged particles that have transmitted a sample. Even if deflection of a charged particle beam irradiated onto a sample is corrected, the image quality of observation images is degraded as long as the influence of the vibrations imparted to the charged particles that have transmitted the sample is not reduced.

Therefore, an object of the present invention is to provide a charged particle beam device capable of reducing the influence of vibrations on charged particles which have been transmitted through a sample, and a control method therefor.

In order to achieve the above-described objective, the present invention provides a charged particle beam device that includes a sample holder that holds a sample, an electron source that emits a charged particle beam to be irradiated onto the sample, a detector that detects transmitted particles that are charged particles which have been transmitted through the sample, and a control unit that generates an observation image of the sample based on a detection signal output from the detector and controls each unit and further includes a vibrometer that measures a vibration of the sample holder, an upper deflector that is disposed between the electron source and the sample holder to deflect the charged particle beam, and a lower deflector that is disposed between the sample holder and the detector to deflect the transmitted particles, in which the control unit controls the upper deflector and the lower deflector based on a measured value of the vibrometer to correct deflection of the transmitted particles together with deflection of the charged particle beam.

Further, the present invention provides a control method for a charged particle beam device including a sample holder that holds a sample, an electron source that emits a charged particle beam to be irradiated onto the sample, a detector that detects transmitted particles that are charged particles which have been transmitted through the sample, a control unit that generates an observation image of the sample based on a detection signal output from the detector and controls each unit, a vibrometer that measures a vibration of the sample holder, an upper deflector that is disposed between the electron source and the sample holder to deflect the charged particle beam, and a lower deflector that is disposed between the sample holder and the detector to deflect the transmitted particles, in which the upper deflector and the lower deflector are controlled based on a measured value in the vibrometer to correct deflection of the transmitted particles together with deflection of the charged particle beam.

According to the present invention, a charged particle beam device capable of reducing the influence of vibrations on charged particles which have been transmitted through a sample and a control method therefor.

### BRIEF DESCRIPTION OF THE DRAWINGS

FIG. 1 is a schematic configuration diagram of a charged particle beam device of a first embodiment;

FIGS. 2A and 2B are diagrams for explaining deflection correction according to a vibration from a sample;

FIG. 3 is a diagram illustrating an example of the flow of processing of the first embodiment;

FIG. 4 is a diagram illustrating an example of the flow of processing of generating a learning model used for deflection correction;

FIGS. 5A to 5E are diagrams for explaining vibration analysis based on observation images;

FIG. 6 is a diagram illustrating an example of a screen for setting machine learning conditions;

FIG. 7 is a diagram illustrating an example of a screen for setting deflection correction conditions;

FIG. 8 is a schematic configuration diagram of a charged particle beam device of a second embodiment; and

FIG. 9 is a schematic configuration diagram of a charged particle beam device of a third embodiment.

### DETAILED DESCRIPTION

Hereinafter, a charged particle beam device of the present invention will be described with reference to the drawings. A charged particle beam device is a transmission electron microscope, a scanning transmission electron microscope, or the like that generates an observation image of a sample by irradiating the sample with a charged particle beam such as an electron beam. Hereinafter, a transmission electron microscope will be described as an example of a charged particle beam device. Note that, in the following description and the accompanying drawings, components having the same functional configuration are denoted by the same reference numerals, and overlapping description is omitted. In addition, an XYZ coordinate system is added to each drawing to indicate the orientation of each drawing.

### First Embodiment

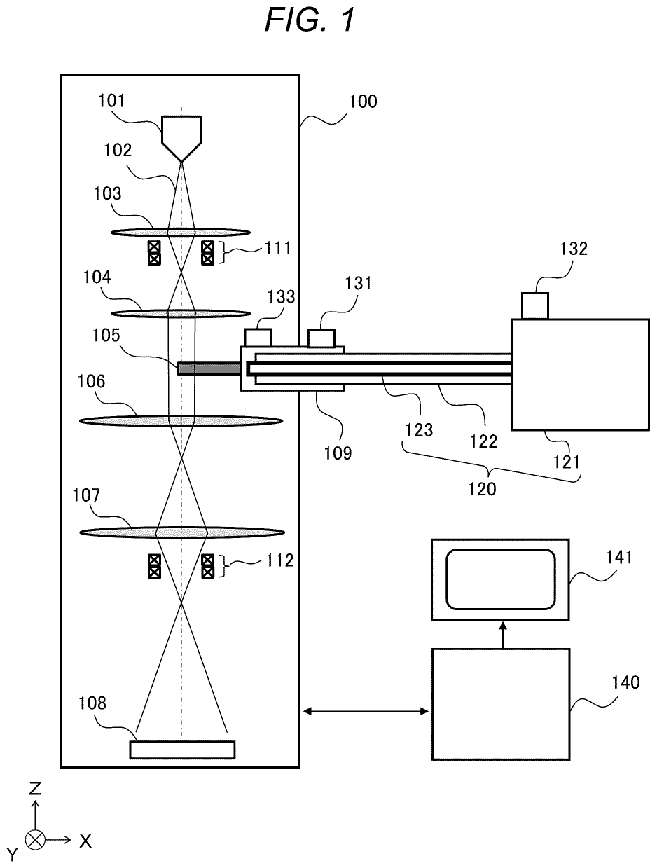

A transmission electron microscope of the first embodiment will be described with reference to FIG. 1. The transmission electron microscope illustrated in FIG. 1 is used to observe a sample 105 cooled to a cryogenic temperature, and includes a mirror body 100, a freezer 120, and a control unit 140. The mirror body 100 includes a sample holder 109, an electron source 101, a first lens 103, a second lens 104, an objective lens 106, a magnifying lens 107, a detector 108, an upper deflector 111, and a lower deflector 112, and the inside thereof is evacuated to a vacuum.

The sample holder 109 holds the sample 105 and is connected to the freezer 120. The electron source 101 emits an electron beam 102 to be irradiated onto the sample 105. The first lens 103 and the second lens 104 are lenses used to adjust the size of the electron beam 102 to be irradiated onto the sample 105. The objective lens 106 and the magnifying lens 107 are lenses that enable an image of transmitted electrons, which are electrons which have been transmitted through the sample 105, to be formed in the detector 108. The detector 108 detects the transmitted electrons and outputs a detection signal.

An upper deflector 111 is disposed between the electron source 101 and the sample holder 109, deflects the electron beam 102, and is, for example, a deflection coil. A lower deflector 112 is disposed between the sample holder 109 and the detector 108, deflects transmitted electrons, and is, for example, a deflection coil.

The freezer 120 is a device that cools the sample 105 via the sample holder 109, and includes a compressor 121, a refrigerant circulation path 122, and a heat insulating tube 123. The compressor 121 compresses a refrigerant such as helium gas and then adiabatically expands the refrigerant to cool the refrigerant. The refrigerant circulation path 122 is a circulation path connecting the compressor 121 and the sample holder 109, in which the refrigerant cooled by the compressor 121 circulates. The heat insulating tube 123 is a tube made of a heat insulator that covers the refrigerant circulation path 122, and protects the cooled refrigerant from the outside air temperature.

The control unit 140 is a device that generates an observation image of the sample 105 based on a detection signal output from the detector 108 and controls each unit of the mirror body 100, and is a so-called computer. A display unit 141 such as a liquid crystal display is connected to the control unit 140. An observation image generated by the control unit 140 is displayed on the display unit 141.

The compressor 121 of the freezer 120 generates vibrations resulting from compression and expansion. A vibration generated by the compressor 121 is transmitted to the sample holder 109 through the refrigerant circulation path 122 and the heat insulating tube 123, and vibrates the sample 105 held by the sample holder 109. The vibration of the sample 105 adversely affects observation images.

Therefore, in the first embodiment, the influence of vibrations is reduced by correcting deflection of the electron beam 102 irradiated onto the sample 105 according to a vibration of the sample 105 and correcting deflection of the transmitted electrons which have been transmitted through the sample 105. In order to measure vibrations of the sample holder 109, a first vibrometer 131 is attached to the sample holder 109. A second vibrometer 132 is attached to the compressor 121 as well to measure vibrations of the compressor 121. Further, in order to measure temperature of the sample holder 109, a thermometer 133 is attached to the sample holder 109.

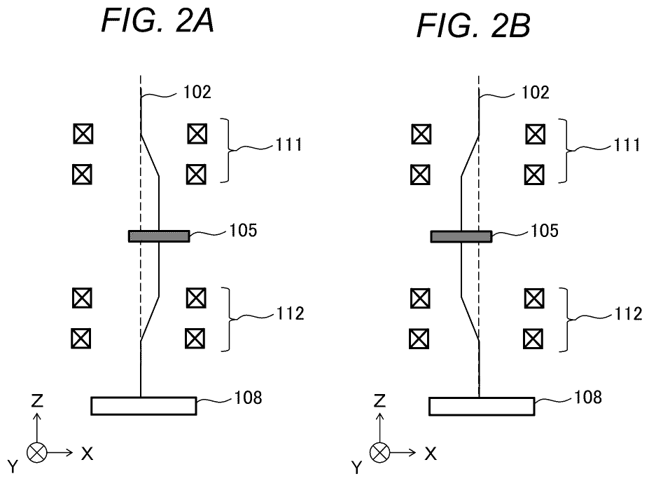

Deflection correction for the electron beam 102 and transmitted electrons according to the vibrations of the sample 105 will be described with reference to FIG. 2. FIG. 2A illustrates a case where the sample 105 moved in the positive direction of the X axis due to a vibration, and FIG. 2B illustrates a case where the sample 105 moved in the negative direction of the X axis.

In FIG. 2A, the center of the sample 105 is irradiated with the electron beam 102 by being deflection-corrected in the positive direction of the X axis along with the movement of the sample 105. Further, the transmitted electrons which have been transmitted through the center of the sample 105 are deflection-corrected in the negative direction of the X axis, and thereby are incident on the center of the detector 108.

In FIG. 2B, the center of the sample 105 is irradiated with the electron beam 102 deflection-corrected in the negative direction of the X axis with the movement of the sample 105, and the transmitted electrons which have been transmitted through the center of the sample 105 are deflection-corrected in the positive direction of the X axis and thereby incident on the center of the detector 108. Note that deflection correction of the electron beam 102 is performed by the upper deflector 111, and deflection correction of the transmitted electrons is performed by the lower deflector 112. Further, the operations of the upper deflector 111 and the lower deflector 112 are controlled by the control unit 140 based on measured values of the first vibrometer 131.

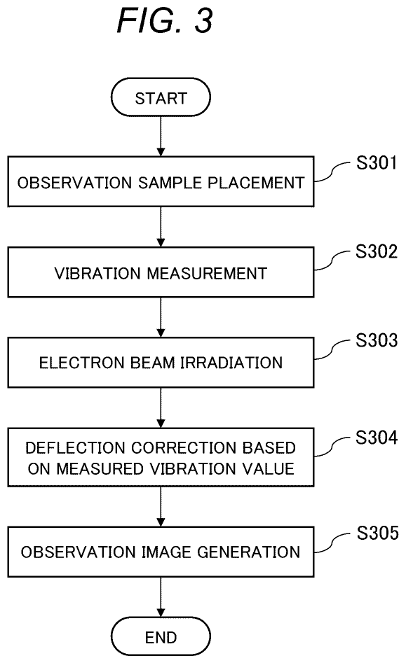

An example of the flow of processing in the first embodiment will be described step by step with reference to FIG. 3.

### (S301)

An observation sample 105 is attached to the sample holder 109 and placed in the mirror body 100. When the inside of the mirror body 100 in which the observation sample 105 is placed is vacuum-evacuated and reaches a predetermined degree of vacuum, cooling of the sample 105 by the freezer 120 is started, and then a vibration of the compressor 121 is transmitted to the sample 105 via the refrigerant circulation path 122, the heat insulating tube 123, and the sample holder 109.

### (S302)

The first vibrometer 131 measures the vibration of the sample holder 109 and outputs a measured value to the control unit 140. The measured value includes the direction, amplitude, and frequency of the vibration.

### (S303)

The control unit 140 controls the electron source 101 to start irradiation of the sample 105 with the electron beam 102. Note that the observation image generated at this stage includes noise due to the vibration of the sample 105.

### (S304)

The control unit 140 controls the upper deflector 111 and the lower deflector 112 based on the measured value of the first vibrometer 131, and deflection-corrects the electron beam 102 irradiated onto the sample 105 and the transmitted electrons which have been transmitted through the sample 105. Note that, since the measured value of the first vibrometer 131 is different from that of the vibration of the sample 105, it is preferable to perform deflection correction according to a value obtained by correcting the measured value of the first vibrometer 131. The deflection-corrected transmitted electrons are detected by the detector 108.

### (S305)

The control unit 140 generates an observation image based on a detection signal output from the detector 108 that has detected the deflection-corrected transmitted electrons. The generated observation image is displayed on the display unit 141.

According to the flow of the processing described with reference to FIG. 3, an observation image in which an adverse effect caused by the vibration of the sample 105 is reduced is obtained. Note that, in S304, instead of correcting the measured value of the first vibrometer 131, a learning model generated in advance by machine learning the relationship between the measured value of the first vibrometer 131 and the vibration of the sample 105 may be used.

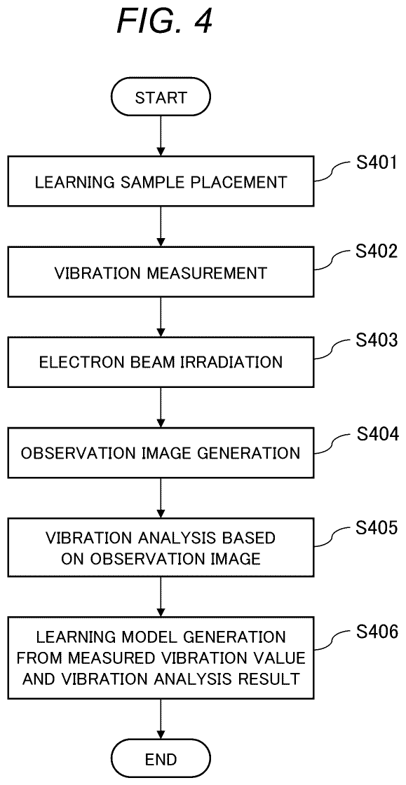

An example of the flow of processing of generating a learning model used for deflection correction will be described step by step with reference to FIG. 4.

### (S401)

A learning sample 105 is attached to the sample holder 109 and placed in the mirror body 100. As the learning sample 105, for example, an amorphous carbon film in which microparticles having a size of about 10 nm are randomly arranged or an amorphous carbon film alone is used.

### (S402)

The first vibrometer 131 starts measuring the vibration of the sample holder 109 and outputs a measured value to the control unit 140. The measured value includes the direction, amplitude, and frequency of the vibration. The vibration source is, for example, the freezer 120 connected to the sample holder.

### (S403)

The control unit 140 controls the electron source 101 and the detector 108, irradiates the sample 105 with the electron beam 102, and detects transmitted electrons. The electron beam 102 irradiated onto the sample 105 may be irradiated with pulses at predetermined intervals or may be continuously irradiated.

### (S404)

The control unit 140 generates an observation image taken when the learning sample 105 is vibrating based on a detection signal output from the detector 108.

### (S405)

The control unit 140 performs vibration analysis based on the observation image generated in S404.

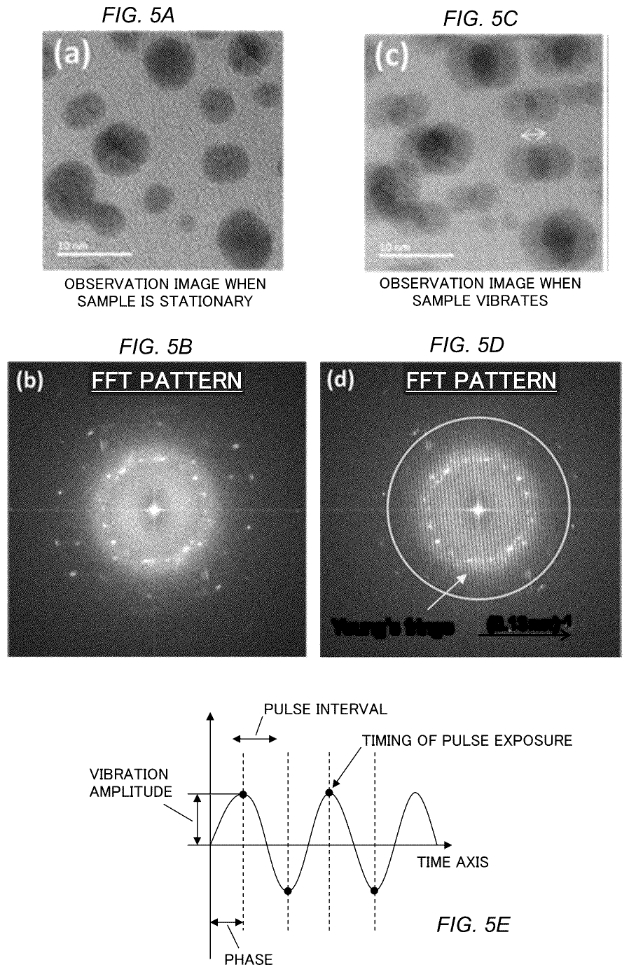

The vibration analysis based on the observation image will be described with reference to FIG. 5. FIG. 5A is an observation image when the learning sample 105 is stationary, and FIG. 5B shows an FFT pattern obtained by performing fast Fourier transform (FFT) processing on the observation image of FIG. 5A. In addition, FIG. 5C is an observation image taken when the learning sample 105 is vibrating, and FIG. 5D shows an FFT pattern of the observation image of FIG. 5C. The observation image of FIG. 5C is a double exposure image obtained at the timings of the pulse exposure indicated by the black circles in FIG. 5E. The movement quantity and direction of the image can be obtained by pattern analysis of Young's fringe based on the double exposure image. Note that the maximum movement quantity can be obtained by performing measurement while varying the phase of the pulse irradiation with respect to the time axis. A distance equal to half the maximum movement quantity corresponds to the vibration amplitude. In addition, the vibration frequency of interest can be selected by varying the pulse interval.

Whereas the microparticles are stationary in FIG. 5A, the microparticles vibrate in a direction indicated by the double-headed arrow in FIG. 5C. In addition, Young's fringes that are not present in FIG. 5B have been generated from the upper left to the lower right in the circle shown in FIG. 5D. Since Young's fringes are derived from the vibration of the sample 105, the amplitude, frequency, and direction of the vibration of the sample 105 are acquired by performing the pattern analysis of Young's fringes in FIG. 5D at various frequencies, and are output as a result of the vibration analysis.

### (S406)

The control unit 140 generates a learning model by performing machine learning using the measured value of the first vibrometer 131 and the result of vibration analysis in S405. The learning model generated in S406 outputs the values of the vibration of the sample 105 when the measured value of the first vibrometer 131 is input. The output values of the vibration include, for example, values of the amplitude, frequency, and direction of the vibration.

According to the flow of the processing described with reference to FIG. 4, a learning model for outputting the vibration of the sample 105 according to the input of the measured value by the first vibrometer 131 is generated. By using the generated learning model in S304 of FIG. 3, deflection correction can be performed with higher accuracy, and the image quality of the observation image of the observation sample 105 is improved.

Note that a measured value of the second vibrometer 132 may be further used for machine learning for generating a learning model. Since the measured value of the second vibrometer 132 is greater than the measured value of the first vibrometer 131, a signal-to-noise ratio (SNR) is improved, and the learning accuracy is also improved.

In addition, a measured value of the thermometer 133 may be further used for machine learning for generating a learning model. Since vibrations of the sample 105 may vary depending on temperature, the learning accuracy is improved by performing machine learning using the measured value of the thermometer 133.

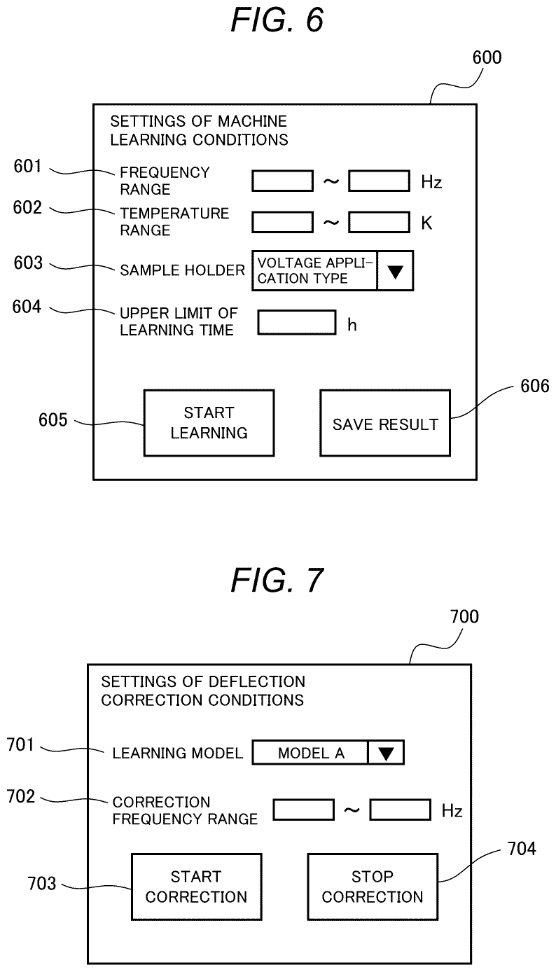

An example of a screen used for setting conditions for machine learning will be described with reference to FIG. 6. The learning condition setting screen 600 illustrated in FIG. 6 includes a frequency range setting unit 601, a temperature range setting unit 602, a sample holder selecting unit 603, a learning time setting unit 604, a start button 605, and a save button 606.

The frequency range to be analyzed in S405 of FIG. 4 is input to the frequency range setting unit 601. A measured temperature range is input to the temperature range setting unit 602 when a measured value of the thermometer 133 is used for machine learning. The sample holder selecting unit 603 selects a type of the sample holder 109. The upper limit time required for machine learning is input to the learning time setting unit 604. The start button 605 is pressed to start machine learning. The save button 606 is pressed to save a result of machine learning.

An example of a screen used for setting conditions for deflection correction will be described with reference to FIG. 7. The correction condition setting screen 700 illustrated in FIG. 7 includes a model selecting unit 701, a frequency range setting unit 702, a start button 703, and a stop button 704.

The model selecting unit 701 selects a learning model to be used for deflection correction from among a plurality of learning models. A frequency range to be corrected is input to the frequency range setting unit 702. The start button 703 is pressed to start deflection correction. The stop button 704 is pressed to stop deflection correction.

### Second Embodiment

In the first embodiment, the transmission electron microscope that corrects deflection of the electron beam 102 and transmitted electrons based on a measured value of the first vibrometer 131 has been described. In a second embodiment, a transmission electron microscope capable of obtaining a hologram image will be described. Note that the same reference numerals are given to the same configurations as those of the first embodiment to simplify the description.

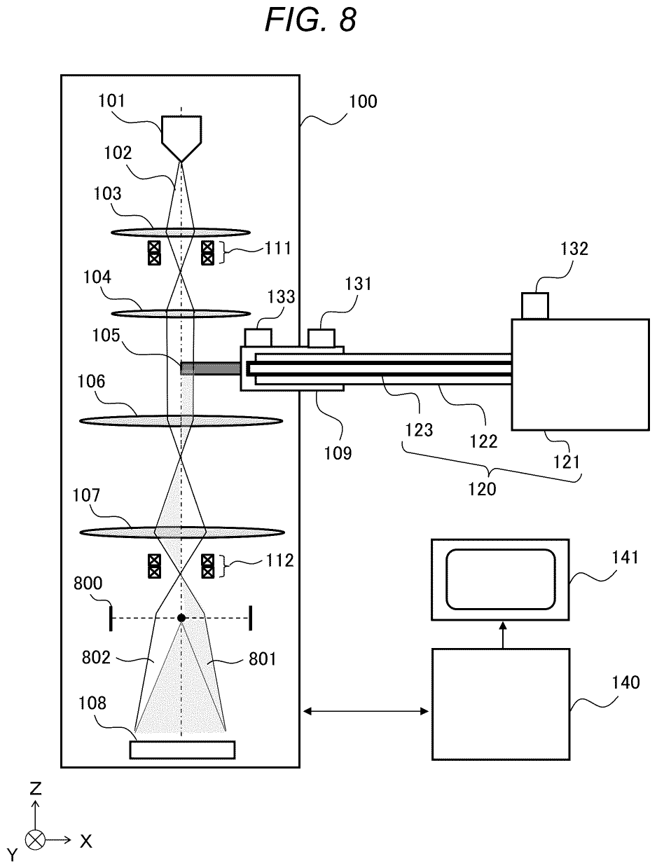

A transmission electron microscope of the second embodiment will be described with reference to FIG. 8. In FIG. 8, an electron bi-prism 800 is added between the lower deflector 112 and the detector 108, unlike in FIG. 1. The electron bi-prism 800 obtains a hologram image by causing an object wave 801 having passed through a sample 105 as an object and a reference wave 802 having passed through a vacuum to interfere with each other.

Also in the second embodiment, a hologram image with reduced influence of vibrations of the sample 105 can be obtained by correcting deflection of the electron beam 102 and transmitted electrons based on a measured value of the first vibrometer 131.

### Third Embodiment

In the first embodiment, the transmission electron microscope that corrects deflection of the electron beam 102 and transmitted electrons based on a measured value of the first vibrometer 131 has been described. In a third embodiment, a scanning transmission electron microscope that obtains a two-dimensional transmission electron image by detecting transmitted electrons while scanning a sample 105 with a narrow electron beam 102 will be described. Note that the same reference numerals are given to the same configurations as those of the first embodiment to simplify the description.

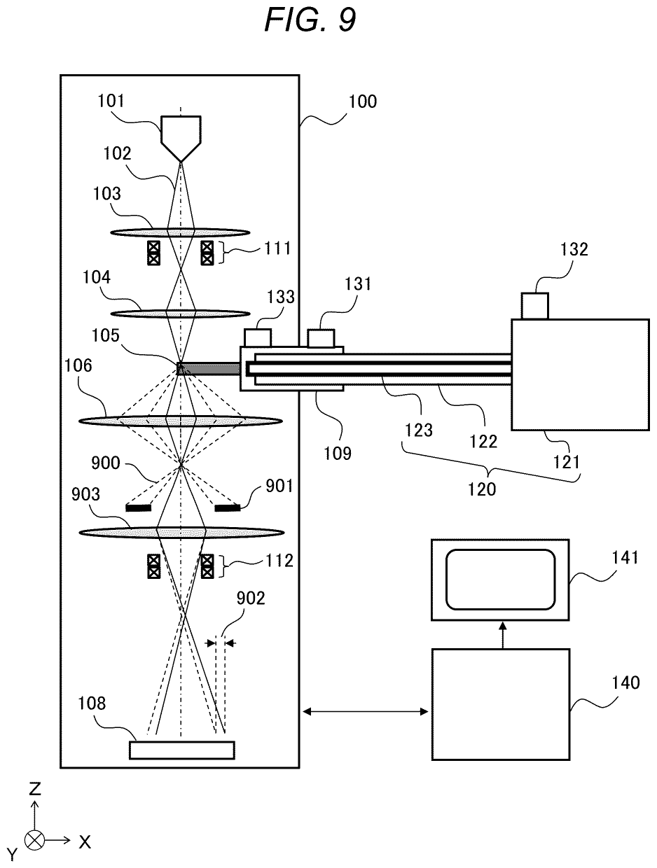

A scanning transmission electron microscope of the third embodiment will be described with reference to FIG. 9. In FIG. 9, the magnifying lens 107 of FIG. 1 is replaced with a projection lens 903, and an annular detector 901 is added between the objective lens 106 and the projection lens 903. The annular detector 901 detects high-angle scattered electrons 900 generated in the sample 105. By using a detection signal output from the annular detector 901, the element number and the sample structure constituting the sample 105 can be obtained. In addition, the electric field and the magnetic field in the sample 105 can be analyzed from a position change quantity 902 of the transmitted electrons in the detector 108.

Also in the third embodiment, a two-dimensional transmitted electron image with reduced influence of vibrations of the sample 105 can be obtained by correcting deflection of the electron beam 102 and transmitted electrons based on a measured value of the first vibrometer 131. In addition, the deflection correction for the electron beam 102 and the transmitted electrons based on the measured value of the first vibrometer 131 can also be applied to a transmission electron microscope including a secondary electron detector, an energy dispersive X-ray detector, and an electron energy loss spectroscopy detector.

The plurality of embodiments of the present invention have been described above. The present invention is not limited to the above embodiments, and can be embodied by modifying the components within the scope not departing from the gist of the invention. In addition, a plurality of components disclosed in the above embodiments may be appropriately combined. Further, some components may be deleted from all the components shown in the above embodiments.

What is claimed is:

1. A charged particle beam device comprising:
a vibrometer that measures a vibration of a sample holder holding a sample;
an upper deflector that is disposed between an electron source that emits a charged particle beam to be irradiated onto the sample and the sample holder to deflect the charged particle beam;
a lower deflector that is disposed between the sample holder and a detector that detects transmitted particles, which are charged particles which have been transmitted through the sample, to deflect the transmitted particles; and
a control unit that controls the upper deflector and the lower deflector based on a measured value of the vibrometer to correct deflection of the transmitted particles together with deflection of the charged particle beam and generates an observation image of the sample based on a detection signal output from the detector.

2. A charged particle beam device according to claim 1, wherein the control unit corrects deflection of the transmitted particles together with deflection of the charged particle beam according to a value output after inputting a measured value of the vibrometer to a learning model generated in advance by machine learning in advance a relationship between a measured value of the vibrometer and a vibration of the sample.

3. The charged particle beam device according to claim 2, wherein the control unit calculates a vibration of the sample by analyzing of a vibration from an image acquired by using a learning sample undergoing vibration.

4. The charged particle beam device according to claim 2, wherein the control unit further uses a measurement value of a thermometer attached to the sample holder for generation of the learning model.

5. The charged particle beam device according to claim 2, further comprising:
a freezer that cools the sample holder; and
a second vibrometer attached to the freezer,
wherein the control unit further uses a measured value of the second vibrometer for generation of the learning model.

6. The charged particle beam device according to claim 1, further comprising an electron bi-prism that obtains a hologram image by causing an object wave having passed through an object and a reference wave having passed through a vacuum to interfere with each other.

7. The charged particle beam device according to claim 1, further comprising an annular detector that detects high-angle scattered electrons from the sample.

8. A control method for a charged particle beam device including a sample holder that holds a sample, an electron source that emits a charged particle beam to be irradiated onto the sample, a detector that detects transmitted particles that are charged particles which have been transmitted through the sample, a control unit that generates an observation image of the sample based on a detection signal output from the detector and controls each unit, a vibrometer that measures a vibration of the sample holder, an upper deflector that is disposed between the electron source and the sample holder to deflect the charged particle beam, and a lower deflector that is disposed between the sample holder and the detector to deflect the transmitted particles, the control method comprising
controlling the upper deflector and the lower deflector based on a measured value in the vibrometer to correct deflection of the transmitted particles together with deflection of the charged particle beam.
